(19) United States
(12) Patent Application Publication
(10) Pub. No.: US 2014/0306250 A1
(43) Pub. Date: Oct. 16, 2014

(54) SOLID-STATE LIGHTING DEVICE AND METHOD OF MANUFACTURING SAME

(71) Applicant: Quarkstar LLC, Las Vegas, NV (US)

(72) Inventors: Robert C. Gardner, Atherton, CA (US); Christopher H. Lowery, Fall River Mills, CA (US); Allan Brent York, Langley (CA)

(73) Assignee: Quarkstar LLC, Las Vegas, NV (US)

(21) Appl. No.: 14/361,916

(22) PCT Filed: Nov. 30, 2012
(86) PCT No.: PCT/US2012/067457

§ 371 Date: May 30, 2014

Related U.S. Application Data
(60) Provisional application No. 61/565,684, filed on Dec. 1, 2011.
(60) Provisional application No. 61/588,531, filed on Jan. 19, 2012.

(51) Int. Cl. H01L 25/075; H01L 33/00; H01L 33/50

(52) U.S. Cl. CPC H01L 25/0753; H01L 33/50; H01L 33/005
USPC 257/89; 438/27

(57) ABSTRACT

The present technology provides a solid-state lighting device and method of manufacturing same. The device can include a carrier substrate having registration features on a first side; light-emitting elements (LEEs) operatively coupled with the registration features; electrically conductive elements (ECEs) operatively coupled with a first side, where the ECEs operatively interconnect the LEEs; and one or more cover layers operatively coupled with the LEEs. The ECEs, furthermore, can be configured to operatively connect the LEEs to a source of power.

### TECHNICAL FIELD

The present technology relates to manufacturing solid-state lighting (SSL) devices and in particular to SSL devices including light-emitting elements (LEEs).

### BACKGROUND

High-power Light Emitting Diodes (LEDs) have become a choice for general solid-state lighting applications. A high power white LED can have luminous efficacies of 90 lumens/watt to beyond 130 lumens/watt. The input power of a contemporary single high-power LED can be around 0.5 watt to more than 10 watts.

Such high-power LEDs can generate considerable heat while being only about one square millimeter in area and relatively thin (e.g., for the 1-3 watt devices), so the demands on packaging can be challenging and expensive. Today, the cost for a bare 1 mm high-power LED chip typically can be well under $1.00 (e.g., $0.10), yet the packaged LED may cost around $1.00-$3.00. This makes a high output (e.g., 3000+lumens) solid-state lighting devices relatively expensive and not a commercially feasible alternative for a standard fluorescent light fixtures, for example, which are commonly used in office, industrial, and other lighting applications. Further, the optics required to convert the high brightness point light sources into a substantially homogeneous, broad angle emission for space illumination where glare control is important, for example, in office lighting applications, is challenging.

The cost of a large area, high-lumen output light source, can be reduced by sandwiching an array of bare LED dies between a bottom sheet having conductors and a top transparent sheet having conductors. The LED dies can have top and bottom electrodes in contact with a set of conductors. When the conductors are energized, the LEDs can emit light. The light sheet can be flexible.

This background information is provided to reveal information believed by the applicant to be of possible relevance to the present technology. No admission is necessarily intended, nor should be construed, that any of the preceding information constitutes prior art against the present technology.

### SUMMARY

An object of the present technology is to provide a solid-state lighting device and method of manufacture thereof. In accordance with an aspect of the present technology, there is provided a flexible lighting device including a carrier substrate that includes a first surface, where the first surface includes multiple registration features; light emitting diode (LED) dies operatively coupled with the registration features; electrical conductors supported by the carrier substrate, where the electrical conductors are configured to electrically connect the LED dies to a source of power, and each LED die has surfaces and contacts, where the contacts are disposed on one or more surfaces and form electrical interconnections with at least a portion of the electrical conductors; and one or more cover layers operatively coupled with the carrier substrate to encapsulate the LED dies inside the registration features, where the electrical interconnections are disposed within portions of the lighting device that are less than a predetermined distance away from a stress-neutral plane of the lighting device.

The foregoing and other embodiments can each optionally include one or more of the following features, alone or in combination. In some implementations, the stress-neutral plane can intersect one or more of the LED dies, one or more of the electrical interconnections, or one or more of the LED dies and one or more of the electrical interconnections. In some implementations, the LED dies can be configured and operatively coupled to emit light substantially away from the first surface. In some implementations, one or more of the cover layers can be light transmissive. In some implementations, the lighting device can further include a light transmissive substance disposed to at least partially surround the LED dies. The light transmissive substance can include silicone and/or a light converting material. In some implementations, the carrier substrate can further include openings to dispose of excess light transmissive substance during operatively coupling the one or more cover layers.

In some implementations, one or more of the cover layers can include openings that substantially correspond to locations of the LED dies. In some implementations, the lighting device can further include a light transmissive substance that at least partially fills at least some of the openings, where the light transmissive substance can provide an optical coupling between the LED dies and the one or more of the cover layers. In some implementations, the first surface can be configured to reflect at least a portion of light emitted from the LED dies. In some implementations, the lighting device can further include an optically reflective interface that can be configured to reflect light emitted from the LED dies. The optically reflective interface can be operatively coupled proximate to the first surface. In some implementations, the optically reflective interface can include an optically reflective layer. In some implementations, the electrical conductors can include the optically reflective interface.

In some implementations, the first surface can be electrically insulating and the electrical conductors can be operatively coupled to the first surface. In some implementations, the lighting device can further include an electrically insulating layer operatively coupled with the first surface, where the electrical conductors can be operatively coupled to the electrically insulating layer. The electrically insulating layer can be configured to reflect light emitted from the LED dies.

In some implementations, the registration features can include corresponding indentations in the carrier substrate, where the indentations can have one or more predetermined shapes. In some implementations, the lighting device can further include a light converting material operatively coupled with the LED dies. In some implementations, one or more of the LED dies can be coated with the light-converting material, and/or one of more of the cover layers can include the light-converting material.

In another aspect, a method of manufacturing a flexible lighting device can include forming registration features in a first surface of a carrier substrate; operatively coupling light emitting diode (LED) dies with corresponding registration features; forming electrical conductors supported by the carrier substrate, where the electrical conductors are configured to electrically connect the LED dies to a source of power, and each LED die has a plurality of surfaces and a plurality of contacts, where the contacts are disposed on one or more surfaces of the surfaces and forming electrical interconnections with at least a portion of the electrical conductors; and operatively coupling one or more cover layers with the carrier substrate to encapsulate the LED dies inside the registration features, where the electrical interconnections are disposed within portions of the lighting device that are less than a predetermined distance away from a stress-neutral plane of the lighting device.

The foregoing and other embodiments can each optionally include one or more of the following features, alone or in combination. In some implementations, the stress-neutral plane can intersect one or more of the LED dies, one or more of the electrical interconnections, or one or more of the LED dies and one or more of the electrical interconnections. In some implementations, the LED dies can be configured and disposed to emit light substantially away from the first surface. In some implementations, one or more of the cover layers can be light transmissive. In some implementations, the method can further include disposing a light transmissive substance to at least partially surround the LED dies. The light transmissive substance can include silicone and/or a light converting material. In some implementations, the method can further include forming openings in the carrier substrate to dispose of excess light transmissive substance during operatively coupling the one or more cover layers.

In some implementations, one or more of the cover layers can include openings that substantially correspond to locations of the LED dies. In some implementations, the method can further include disposing a light transmissive substance to at least partially fill at least some of the openings, where the light transmissive substance can provide an optical coupling between the LED dies and the one or more of the cover layers. In some implementations, the first surface can be configured to reflect at least a portion of light emitted from the LED dies. In some implementations, the method can further include operatively coupling an optically reflective interface to the flexible lighting device, where the optically reflective interface can be configured to reflect light emitted from the LED dies. The optically reflective interface can be operatively coupled proximate to the first surface. In some implementations, the optically reflective interface can include an optically reflective layer. In some implementations, the electrical conductors can include the optically reflective interface.

In some implementations, the first surface can be electrically insulating and the electrical conductors can be operatively coupled to the first surface. In some implementations, the method can further include operatively coupling an electrically insulating layer with the first surface; and operatively coupling the electrical conductors to the electrically insulating layer. The electrically insulating layer can be configured to reflect light emitted from the LED dies. In some implementations, forming the registration features can include forming indentations in the first surface of the carrier substrate. In some implementations, the method can further include operatively coupling a light converting material with the LED dies. In some implementations, one or more of the LED dies can be coated with the light-converting material, or one of more of the cover layers can include the light-converting material.

In another aspect, a lighting device includes a carrier substrate having indentations on a first side; light-emitting elements (LEEs) disposed within respective indentations; electrically conductive elements (ECEs) supported by the carrier substrate, where the ECEs are configured to electrically connect the LEEs to a source of power, and each LEE has surfaces and contacts, where the contacts are disposed on one or more of the surfaces and form electrical interconnections with the ECEs; and one or more cover layers disposed on the carrier substrate to encapsulate the LEEs within the indentations, where the electrical interconnections are disposed within portions of the lighting device that are less than a predetermined distance away from a stress-neutral plane of the lighting device.

The foregoing and other embodiments can each optionally include one or more of the following features, alone or in combination. In some implementations, the stress-neutral plane can be substantially within the LEEs of the lighting device, within the electrical interconnections of the lighting device, or within the electrical interconnections and the plurality of LEEs of the lighting device.

In another aspect, a method of manufacturing a lighting device includes forming indentations on a first side of a carrier substrate; disposing electrically conductive elements (ECEs) within respective indentations on the first side of the carrier substrate so that each LEE is coupled with a corresponding indentation; forming electrical interconnections between the LEEs and the ECEs, where each LEE has surfaces and contacts, where the contacts are disposed on one or more of the surfaces and form part of the electrical interconnections; and disposing one or more cover layers on the carrier substrate to encapsulate the LEEs within the indentations, where the electrical interconnections are disposed within portions of the lighting device that are less than a predetermined distance away from a stress-neutral plane of the lighting device.

The foregoing and other embodiments can each optionally include one or more of the following features, alone or in combination. In some implementations, the stress-neutral plane can be substantially within the LEEs of the lighting device, within the electrical interconnections of the lighting device, or within the electrical interconnections and the LEEs of the lighting device.

In another aspect, a lighting device includes a carrier substrate having indentations on a first side; light-emitting elements (LEEs) disposed within respective indentations; electrically conductive elements (ECEs) supported by the carrier substrate, where the ECEs are configured to electrically connect the LEEs to a source of power, and each LEE has surfaces and contacts, where the contacts are disposed on one or more of the surfaces and form electrical interconnections with the ECEs; and one or more cover layers disposed on the carrier substrate to encapsulate the LEEs within the indentations, where the electrical interconnections are disposed within portions of the lighting device that are exposed to mechanical stress below predetermined levels during bending and/or shearing of the lighting device.

In another aspect, a method of manufacturing a lighting device includes forming indentations on a first side of a carrier substrate; disposing electrically conductive elements (ECEs) within respective indentations on the first side of the carrier substrate so that each LEE is coupled with a corresponding indentation; forming electrical interconnections between the LEEs and the ECEs, where each LEE has surfaces and contacts, where the contacts are disposed on one or more of the surfaces and form part of the electrical interconnections; and disposing one or more cover layers on the carrier substrate to encapsulate the LEEs within the indentations, where the electrical interconnections are disposed within portions of the lighting device that are exposed to mechanical stress below predetermined levels during bending and shearing of the lighting device.

In another aspect, a method of manufacturing a lighting device includes forming indentations on a first side of a carrier substrate; disposing electrically conductive elements (ECEs) within respective indentations on the first side of the carrier substrate so that each LEE is coupled with a corresponding indentation; forming electrical interconnections between the LEEs and the ECEs, where each LEE has surfaces and contacts, where the contacts are disposed on one or more of the surfaces and form part of the electrical interconnections; and disposing one or more cover layers on the carrier substrate to encapsulate the LEEs within the indentations, where the indentations are configured to enable disposition of the electrical interconnections within portions of the lighting device that are exposed to mechanical stress below predetermined levels during bending and shearing of the lighting device.

In another aspect, a method of manufacturing a lighting device includes forming registration features on a first side of a carrier substrate by forming indentations in the carrier substrate, where the indentations having one or more predetermined shapes; disposing electrically conductive elements (ECEs) within respective indentations on the first side of the carrier substrate so that each LEE is coupled with a corresponding indentation; forming electrical interconnections between the LEEs and the ECEs, where each LEE has surfaces and, where the contacts are disposed on one or more of the surfaces and form part of the electrical interconnections; and disposing one or more cover layers on the carrier substrate to encapsulate the LEEs within the indentations, where the indentations are formed to enable disposition of the electrical interconnections within portions of the lighting device that are exposed to mechanical stress below predetermined levels during bending and shearing of the lighting device.

In another aspect, a method of manufacturing a lighting device includes providing a carrier substrate; forming registration features in a first surface of the carrier substrate, where a surface of each of the registration features has a predetermined shape; operatively coupling non-packaged light emitting diodes (LED) dies with the registration features using a fluidic self-assembly process based, at least in part, on hydrophobic or hydrophilic properties of a surface of the LED dies, the surface of the registration features, and the first surface of the carrier substrate outside of the registration features, where the surface of the LED dies substantially conforms with the surface of the registration features; operatively coupling electrical conductors with the first surface of the carrier substrate; forming electrical interconnections between the LED dies and the electrical conductors; and operatively coupling one or more cover layers with the carrier substrate to encapsulate the LED dies inside the registration features.

The foregoing and other embodiments can each optionally include one or more of the following features, alone or in combination. In some implementations, the surface of the LED dies and the surface of the registration features can be hydrophilic, and the surface of the carrier substrate outside of the registration features can be hydrophobic. In some implementations, the surface of the LED dies and the surface of the registration features can be hydrophobic, and the surface of the carrier substrate outside of the registration features can be hydrophilic.

In some implementations, the method can further include disposing a light transmissive substance to at least partially surround the LED dies. In some implementations, the method can further include forming openings in the carrier substrate to dispose of excess light transmissive substance during operatively coupling the one or more cover layers. The light transmissive substance can include silicone. In some implementations, the light transmissive substance can be in a fluidic state when disposed. In some implementations, the method can further include curing the light transmissive substance.

In some implementations, the method can further include forming openings into one or more of the cover layers, where the openings can substantially correspond to locations of the LED dies. The openings can be formed, for example, by using one or more of a cutter, a die cutter, a saw, a laser, or a water jet. In some implementations, the method can further include disposing a light transmissive substance to at least partially fill at least some of the openings, where the light transmissive substance can provide an optical coupling between the LED dies and the one or more of the cover layers.

In some implementations, the method can further include forming an optically reflective interface configured to reflect light emitted from the LED dies. The optically reflective interface can be formed proximate the first surface. In some implementations, forming the optically reflective interface can include disposing an optically reflective layer. The optically reflective layer can include a web format. In some implementations, the optically reflective layer can be disposed in an initially fluidic state.

In some implementations, the method can further include operatively coupling an electrically-insulating layer with the first surface; and operatively coupling the electrical conductors with the electrically insulating layer. The electrically-insulating layer can include a web format. In some implementations, the electrically-insulating layer can be operatively coupled in an initially fluidic state.

In some implementations, forming the registration features can include forming indentations in the first surface of the carrier substrate. The indentations can be formed by embossing. In some implementations, the method can further include operatively coupling a light converting material with the LED dies. In some implementations, one or more of the LED dies can be coated with the light-converting material, or one of more of the cover layers can include the light-converting material.

In some implementations, the carrier substrate and/or one or more of the cover layers, can include a web format. In some implementations, one or more of the cover layers can be operatively coupled in an initially fluidic state. In some implementations, the method can further include removing the carrier substrate after operatively coupling one or more of the cover layers.

Among other advantages, embodiments of the present technology include improvements in manufacturing of light emitting devices. For example, an embodiment of the present technology features self-assembly of LEE's on a substrate. Such self-assembly can be implemented, for example, on large area substrates in a continuous manner. Accordingly, embodiments can feature efficient roll-to-roll manufacturing of light emitting devices.

Alternatively, or additionally, embodiments can feature light emitting devices that can exhibit high mechanical stability and durability. For example, in some embodiments, elements of the light emitting devices that are sensitive to mechanical stresses (e.g., points of electrical contact) can be positioned in portions of a light emitting device where stresses are relatively low. Such positioning can be achieved with efficient, scalable manufacturing methods, such as continuous web-based manufacturing methods.

### BRIEF DESCRIPTION OF THE FIGURES

The below described drawings are presented to illustrate various aspects of embodiments of the present technology.

FIG. 1A shows a sectional view of a portion of a lighting device according to embodiments of the present technology.

FIG. 1B shows an example schematic of a lighting device with a stress-neutral plane.

FIGS. 1C to 1F show example cross sections of portions of lighting devices according to embodiments of the present technology that have different locations of stress-neutral planes.

FIG. 1G shows a sectional view of a flexible lighting device with preferred bending locations.

FIG. 2 shows a sequence of an example manufacturing method of a lighting device according to embodiments of the present technology.

FIG. 3 shows another sequence of an example manufacturing method of lighting devices according to embodiments of the present technology.

FIG. 4 shows another sequence of an example manufacturing method of a lighting device according to embodiments of the present technology.

Like reference symbols in the various drawings indicate like elements.

### DETAILED DESCRIPTION

### Definitions

The term “light-converting material” (LCM) is used to define a material, which can absorb photons according to a first spectral distribution and can emit photons according to a second spectral distribution. Light-converting material can be referred to as “color-converting material.” Light-converting materials can include photoluminescent substances, fluorescent substances, phosphors, quantum dots, semiconductor-based optical converters, or the like. Light-converting materials can comprise rare-earth or other elements.

The term “light-emitting element” (LEE) is used to define any device that emits radiation in any region or combination of regions of the electromagnetic spectrum, including, the visible region, infrared and/or ultraviolet region, when activated by applying a potential difference across it or passing a current through it, for example. Therefore a light-emitting element can have monochromatic, quasi-monochromatic, polychromatic or broadband spectral emission characteristics. Examples of light-emitting elements include semiconductor, organic, or polymer/polymeric light-emitting diodes, optically pumped phosphor coated light-emitting diodes, optically pumped nanocrystal light-emitting diodes or any other light-emitting devices, as would be readily understood by a person skilled in the art. Furthermore, the term light-emitting element may be used to refer to the specific device that emits the radiation, for example a LED die, and/or refer to a combination of the specific device that emits the radiation together with a housing or package within which the specific device or devices can be placed. LEEs can have a substantially rectilinear, cuboid, mesa, truncated pyramid, or other shape. A LEE can be configured with electrical contacts in a horizontal (also referred to as lateral), vertical, or other arrangement relative to an orientation of a junction within the LEE or the shape of the LEE. Corresponding LEEs can be referred to herein, for example, as horizontal, lateral, or vertical LEEs, LED dies or LEDs. Further examples of light emitting elements include lasers, specifically semiconductor lasers, such as VCSEL (Vertical cavity surface emitting lasers) and edge emitting lasers. Further examples may include superluminescent diodes and other superluminescent devices.

The terms “light-transmissive” and “light-transmissivity” are used with reference to a component or material to define that light provided thereto can cause light to emerge from the component or the material. Examples for light-transmissive and light-transmissivity include transparency, translucency and photoluminescence.

As used herein, the term “about” refers to a +/−10% variation from the nominal value. It is to be understood that such a variation can be included in any value provided herein.

Unless defined otherwise, all technical and scientific terms used herein have the same meaning as commonly understood by one of ordinary skill in the art with respect to the present technology.

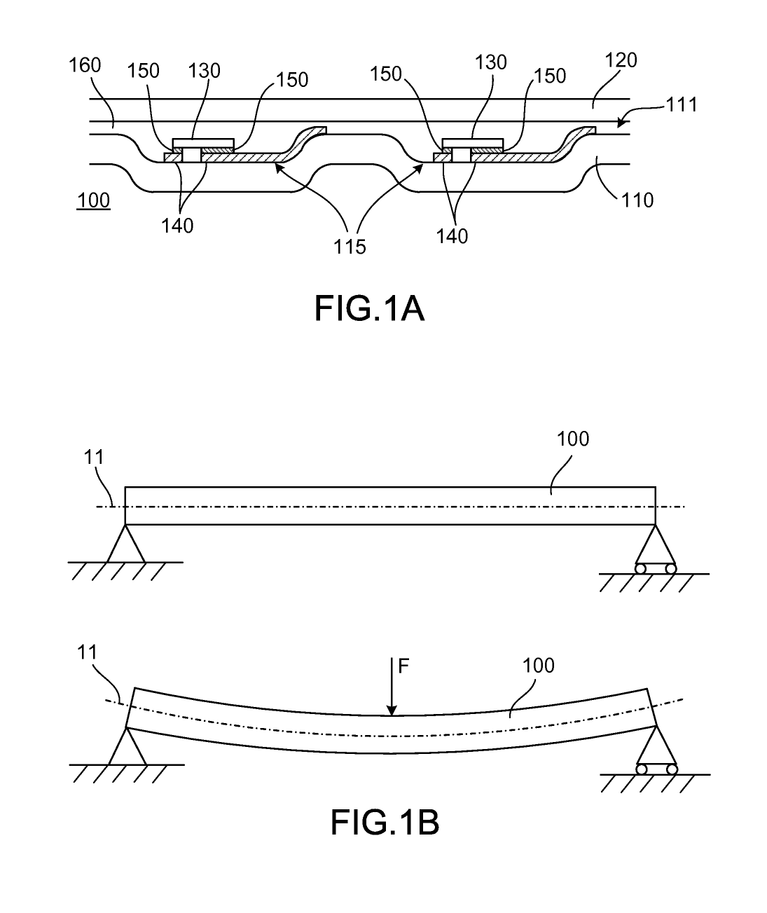

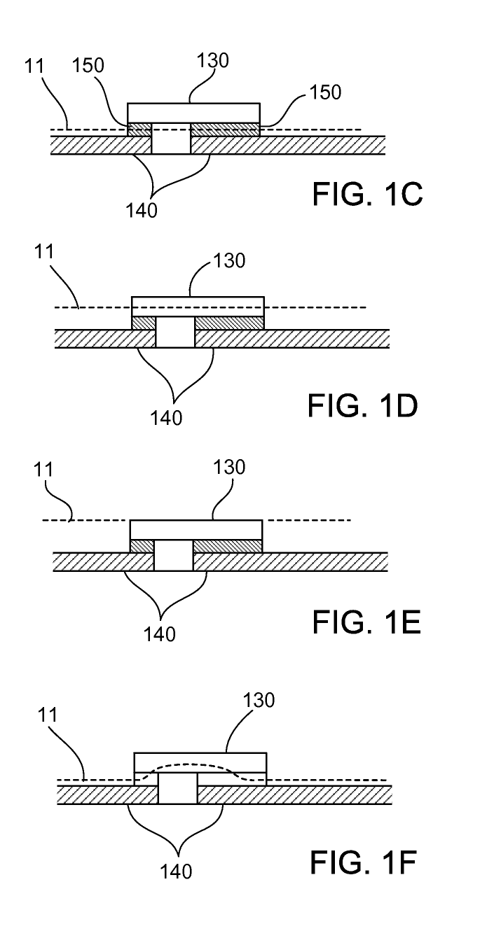

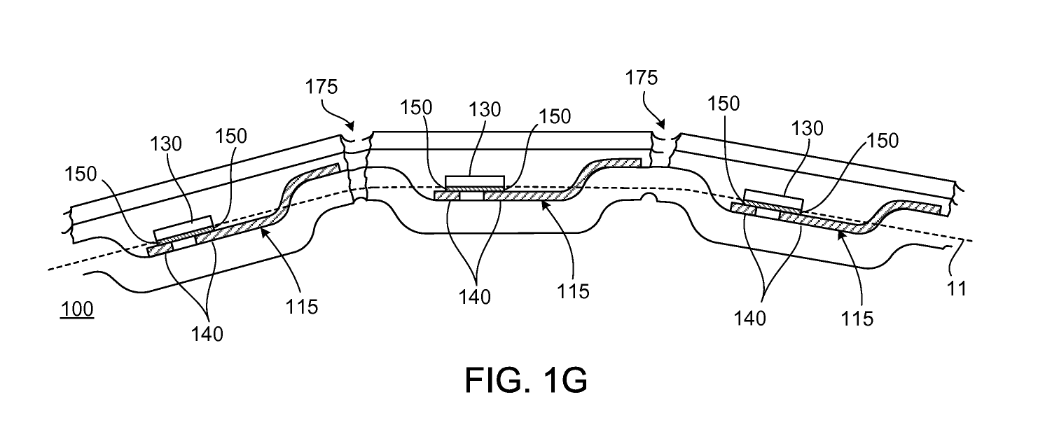

According to aspects of the present technology, there is provided a lighting device and a method of manufacturing a lighting device. FIG. 1A shows a cross-section of a portion of a lighting device 100 including a carrier substrate 110 and a plurality of registration features 115. The registration features 115 can be associated with one or more sides of the carrier substrate, for example with a first side 111. The registration features can include indentations (only two are shown) or other forms (not shown) of registration features. Registration features can be configured to include, for example, indentations, pattern recognition targets, fiducial markers, feature contour changes, registration features as used in optical pattern recognition software or other registration features. A plurality of light-emitting elements (LEEs) 130 can be operatively coupled with the registration features 115. The LEEs 130 can be configured as lateral LEEs with their electrical contacts (also referred to as electrodes) on one side. In some embodiments, LEEs with electrical contacts on opposite sides (also referred to as vertical LEEs) or other LEEs can be used. Electrically conductive elements (ECEs) 140 can be operatively coupled with the first side 111 and operatively interconnect the LEEs 130 via electrical interconnections 150. In some embodiments, the ECEs do not (not shown) extend into the indentations. Furthermore, one or more cover layers 120 can be operatively coupled with the LEEs. The ECEs can be configured to operatively connect the LEEs to a source of power (not shown). Cover layers can be disposed on one or more sides of the lighting device 100.

In some embodiments, the LEEs 130 can be small or large in size relative to the registration features 115. According to an embodiment, the registration features 115 can include indentations and the LEEs 130 can be substantially the same size as the indentations. In some embodiments, electrical interconnections 150 can be located on one or more surfaces of an LEE including, for example, surfaces not facing the carrier substrate (not shown). The registration features 115 can be employed, for example, in the disposition and/or alignment of the LEEs relative to the carrier substrate 110. In some embodiments, disposition of LEEs relative to the registration features can be performed manually or automatically, performed in a self-assembly process, or other form of disposition.

In some embodiments, the lighting device and/or one or more of its components can be configured, for example, in a planar, curved, plate, tile, sheet, strip, thread, web or other format. In some embodiments, the lighting device can include one or more LEEs per unit length or area. For example, a lighting device configured as a sheet can include less than 1 to 10³ LEEs per square centimeter, or more than 10³ LEEs per square centimeter. In some embodiments, LEE densities can be determined based on the size, brightness, power and/or other aspects of the LEEs, the properties of the lighting device, and/or aspects of manufacturing methods of the lighting device. For example, the lighting device can be configured to output substantially equal amounts of light per unit area or length by including high brightness LEEs at a low density or low brightness LEEs at a high density. A particular combination can be determined based on factors including optical, thermal and/or electromechanical design of the lighting device, LEE lifetime considerations, and/or other factors.

In some embodiments, the lighting device can be configured to provide predetermined rigidity, flexibility and/or ductility, or other properties. One or more properties of the lighting device and/or one or more of its components can be isotropic or anisotropic. Different components may exhibit different properties. For example, different components can be provided in different formats and/or provide different degrees of rigidity, flexibility, ductility, coefficient of thermal expansion, or other mechanical properties. Furthermore, different components can have different optical, electrical and/or thermal properties including transparency, translucency or other light-transmissivity properties, electrical and/or thermal conductivity, heat capacity, diffusion resistance to water or other substances, ultraviolet-light resistance, susceptibility to aging, comply with fire resistance and safety regulations including heat deflection, flame propagation, release of toxic substances and so forth.

In some embodiments, different components of the lighting device can be configured to provide adequately matched thermal expansion coefficients to avoid de-bonding of components due to differential thermal expansion. Differential thermal expansion can be differently matched in different directions between different components.

In some embodiments, the lighting device can be configured so that the LEEs, the electrical interconnections between the LEEs and the ECEs and/or other components of the lighting device are disposed within portions of the lighting device that are exposed to mechanical stress below predetermined levels during bending and shearing of the lighting device. Electrical interconnections between an LEE and respective ECEs can be formed on one or more surfaces of such an LEE. For example, the LEEs can be configured as lateral or vertical LEEs.

In some embodiments, the predetermined mechanical stress level can be below a stress level at which separation of the electrical interconnection between the LEEs and ECEs may occur. The separation stress level can be dependent on the number of connections, material properties of the connecting portions of the LEEs and ECEs, bonding materials, dynamic and static loads, bending frequencies, etc. For example, the predetermined mechanical stress level can be 45-55% of the separation stress level of the electrical interconnections for standard light sheet applications, 25-35% of the separation stress level of the electrical interconnections for light sheet applications with exposure to higher loads (e.g., high bending frequency, dynamic applications, or high shear and/or bending forces), or 70-80% of the separation stress level of the electrical interconnections for light sheet applications with minimal exposure to loads (e.g., low bending frequency, static applications, or low shear and/or bending forces).

In some embodiments, components of the lighting device, such as the electrical interconnections and/or the LEEs, can be placed within a predetermined distance from the stress-neutral plane of the lighting device. For example, the electrical interconnections and/or LEEs can be placed within a range of +/−10 microns, +/−15 micron, +/−20 microns, or +/−150 microns of the stress-neutral plane. Moreover, the range of the predetermined distance can also be expressed in terms of a fraction of the electrical interconnection thickness Δz. For example, the range can be +/−25%, +/−50%, or +/−75% of Δz.

In some embodiments, the predetermined distance from the stress-neutral plane can be dependent on the thickness of the lighting device. In some embodiments, the arrangement and configuration of the registration features (e.g., indentations) can define the location of the electrical interconnections or LEEs within the lighting device.

FIG. 1B shows an example schematic of a lighting device 100 with a stress-neutral plane 11. The stress-neutral plane 11 of a lighting device (e.g., a light sheet) can be a longitudinal plane of zero stress during bending of the lighting device, for example, by application of a force to the lighting device. The location of the stress-neutral plane 11 within the lighting device can be dependent, for example, on the structural configuration, composition, or material properties of the lighting device. In some embodiments, the stress-neutral plane 11 can be arranged so that it, for example, passes through the electrical interconnections of the LEEs residing in the registration features and the ECEs to minimize mechanical stress in the electrical interconnections. In some embodiments, the registration features can be arranged in alternating configuration on either side of the carrier substrate (e.g., an embossed sheet), such that the stress-neutral plane substantially passes through the electrical interconnections of the LEEs and ECEs.

The stress-neutral plane 11 can be determined, for example, by using formulae and mathematical tools (e.g., Computer Aided Design (CAD) programs). A finite element mesh can be created to show the forces exerted on the components in the structure under analysis. A neutral axis can be an axis in the cross section of a lighting device (e.g., a light sheet) along which there are no longitudinal stresses or strains. A stress-neutral plane can be defined by a series of neutral axis of a lighting device. If the section is symmetric, isotropic and is not curved before a bend occurs, then the neutral axis is at the geometric centroid. With respect to the neutral axis one side of the lighting device is in a state of tension, while the opposite side is in a state of compression. If the lighting device undergoes uniform bending, the stress-neutral plane is defined by

γ_{xy}=γ_{xz}=τ_{xy}=τ_{xz}=0

where γ is the shear strain and τ is the shear stress. The top of the lighting device may be exposed to a compressive (negative) strain, and the bottom of the lighting device may be exposed to a tensile (positive) strain, or vice versa. According to the Intermediate Value Theorem, there is some point between the top and the bottom of the lighting device that is not exposed to strain, since the strain in a lighting device is a continuous function.

For example, L refers to the original length of the lighting device cross section (span), ∈(y) refers to the strain as a function of a coordinate on the face of the lighting device cross section, σ(y) refers to the stress as a function of a coordinate on the face of the lighting device cross section, ρ refers to the radius of curvature of the lighting device cross section at its neutral axis, and θ refers to the bend angle.

If the bending is uniform, the following formula applies to determine the strain as a function of y:

$${ε}_{x} ( y ) = \frac{L ( y ) - L}{L} = \frac{θ ( ρ - y ) - θρ}{θρ} = \frac{- y θ}{ρθ} = \frac{- y}{ρ}$$

Therefore the longitudinal normal strain ∈ₓ can vary linearly with the distance y from the neutral axis. Denoting ∈ₘ as the maximum strain in the lighting device cross section (at a distance c from the neutral axis), the following formula applies:

$${ε}_{m} = \frac{c}{ρ}$$

Therefore:

$$ρ = \frac{c}{{ε}_{m}}$$

Substituted into the original expression:

$${ε}_{x} ( y ) = \frac{- {ε}_{m} y}{c}$$

According to Hooke's Law, the stress in the lighting device cross section is proportional to the strain by E, the modulus of Elasticity:

σₓ=E∈ₓ

Therefore:

$$E {ε}_{x} ( y ) = \frac{- E {ε}_{m} y}{c}$$

$${σ}_{x} ( y ) = \frac{- {σ}_{m} y}{c}$$

According to statics, a moment (e.g., pure bending) consists of equal and opposite forces. Therefore, the sum of forces across the cross section must be 0.

∫σₓdA=0

Therefore:

$$\int \frac{- {σ}_{m} y}{c} d A = 0$$

Since y denotes the distance from the neutral axis to any point on the face of the lighting device, y is the only variable that changes with respect to dA. Therefore:

∫ydA=0

Therefore the first moment of the cross section about its neutral axis must be zero and the neutral axis lies on the centroid of the cross section. The neutral axis does not change in length when under bending, because there are no bending stresses in the neutral axis. However, there can be shear stresses (τ) in the neutral axis, zero in the middle of the span but increasing towards the ends of the lighting device cross section, as can be seen in this function (Jourawski's formula):

τ=(T*Q)/(ω*I)

T=shear force.
Q=first moment of area of the section above/below the neutral axis.
w=width of the lighting device cross section.
I=second moment of area of the beam.

Electrical interconnections of a lighting device can be exposed to limited mechanical stress during bending and/or shearing of the lighting device. FIGS. 1C, 1D, 1E, and 1F show examples in which notional stress-neutral planes 11 defined by zero shear and/or bending stress within lateral and/or perpendicular directions within the lighting device passes through the electrical interconnections (FIG. 1C), the LEEs (FIG. 1D), a face of the LEEs, e.g., opposite the electrical interconnections, (FIG. 1E), or the electrical interconnections and the LEEs (FIG. 1F).

In some embodiments, the stress-neutral plane can be substantially within the LEEs, the electrical interconnections, or the LEEs and the electrical interconnections. Substantially within the LEEs or electrical interconnections refers to the stress-neutral plane passing through the LEEs and/or the electrical interconnections respectively. For example, the stress-neutral plane can pass through the LEEs of the lighting device between two opposite faces of the LEEs, or the stress-neutral place can pass through the electrical interconnections between opposite faces of the electrical interconnections.

In other embodiments, the notional stress-neutral plane 11 can pass through other portion of the lighting device (not illustrated). A stress-neutral plane does not have to be planar. The lighting device can be configured to minimize stress and strain on the LEEs and/or electrical interconnections between the LEEs and the ECEs. The location of the stress-neutral plane can be determined based on the geometries and/or composition of the components of the lighting device.

In some embodiments, a flexible lighting device can include a carrier substrate with a first surface including multiple registration features (e.g., indentations). The registration features can have a predetermined shape to accommodate LEEs. The carrier substrate can support electrical conductors that can be configured to electrically connect the LEEs to a source of power and the LEEs can be operatively coupled with the registration features. Each LEE can have multiple surfaces and contacts, where the contacts can be disposed on one or more surfaces of the LEE and form an electrical connection with the electrical conductors. One or more cover layers can be operatively coupled with the carrier substrate to encapsulate the LEEs inside the registration features, where the electrical connections can be disposed within portions of the lighting device that are less than a predetermined distance away from the stress-neutral place of the lighting device. In some embodiments, the stress-neutral plane can intersect one or more to the LEEs, one or more of the electrical connections, or both.

In some embodiments, manufacture of the lighting device can include providing a carrier substrate, forming a plurality of registration features on a first side of the carrier substrate, operatively coupling a plurality of electrically conductive elements (ECEs) with a first side of the carrier substrate, operatively coupling a plurality of light-emitting elements (LEEs) with the registration features; forming electrical interconnections between the LEEs and the ECEs; and operatively coupling one or more cover layers with the LEEs.

In some embodiments, the manufacture can include formation of openings in the carrier substrate and/or one or more of the cover layers, one or more ways of operatively coupling of light-converting material (LCM) and/or one or more light-transmissive substances with the LEEs.

In some embodiments, manufacturing can be performed in a number of sequences. Different sequences may yield like or equal lighting devices.

In some embodiments, components can be bonded or otherwise durably disposed for example by welding, soldering, gluing, cementing, etc. Furthermore, components can be durably disposed relative to one another in a nested, embedded or otherwise matching fashion in which at least a portion of a first component matches in form and size at least a portion of a second component and where a third component is used to arrest movement between the first and second component. For example, registration features that are shape-specific slip fit placements in fluidic self-assembly can be used to dispose LEEs without bonding the LEEs to a carrier substrate or a cover layer in a conventional sense. Such registration features can be configured to secure the LEEs in place once the carrier substrate and the cover layer are bonded together.

Bonds can be achieved with or without adhesive. Forming a bond with adhesive can include curing one or more types of adhesive including hot-melt adhesive, glue or other forms of adhesive. Forming a bond can include heating and pressure application to two or more components, application of ultrasonic or electromagnetic waves, and/or employ the use of adhesive. Such and other processes may be considered to form part of a lamination process.

In some embodiments, one or more components can be formed from a fluid precursor material with suitable viscosity to facilitate deposition. The fluid precursor material can be cured into a solid or semi-solid modification to provide the corresponding component. Components can be formed from a fluid precursor material disposed on a suitable substrate. Such a substrate may form part of the lighting device.

In some embodiments, the lighting device can be configured to emit light through one or more sides. Lighting devices, irrespective of whether they are considered thin, can be configured to emit light from two opposing sides and optionally along edges of the lighting device. Light emitted through a particular side can have substantially homogenous properties or properties that vary across the extension of the respective side. Light emitted from different sides can have different properties. Such properties can include brightness, color and other optical properties.

Components of the lighting device, including ECEs, electrical interconnections and/or other components can be configured to maintain operative function in effect of manufacture and nominally permitted flexure, if any, during operation of the lighting device. To mitigate the risk for open circuit formation, such components can be configured and formed in adequate ways to withstand certain forms of thermally or mechanically induced stress.

Components of the lighting device, including the carrier substrate, the registration features, the cover layers and or other components, can be configured to include refractive or other optical elements that can redirect light in a predetermined manner. For example, one or more cover layers can include a plurality of microlenses, prisms, or other optical elements.

### Carrier Substrate

In some embodiments, the carrier substrate can include one or more layers. Each layer can be formed from one or more elemental or compound materials. Different layers can have different properties and can be bonded to one another. The carrier substrate can include materials including organic, inorganic, metallic, non-metallic, oxides, ceramic, dielectric, adhesives or other materials. The carrier substrate can include or be coated, for example, with organic or inorganic materials such as polypropylene (PP), polyethylene terephthalate (PET), polycarbonate, polyvinylidene fluoride such as Kynar™, lacquer, acrylic, rubber, polyphenylene sulfide (PPS) such as Ryton™, polysulfone, polyetherimide (PEI) such as Ultem™, polyetheretherketone (PEEK), polyphenylene oxide (PPO) such as Noryl™, aluminum, titanium oxides such as TiO₂, LCM (light-converting material), one or more types of glass, silicate and/or other materials or compounds thereof. Fibers or other particles of glass or other materials can be embedded in the carrier substrate and/or other components of the lighting device to provide predetermined mechanical, optical or other properties. For example, inclusion of glass fibers and/or spheres can provide components with good mechanical strength, predetermined optical and/or other properties, depending in density and/or shape thereof.

The carrier substrate can be configured to provide or be associated with other components to provide predetermined optical and/or electrical properties on or proximate to one or more sides of the carrier substrate. For example, the carrier substrate can have one or more optically reflective surfaces and/or one or more electrically insulating surfaces or both, or suitable layers can be attached to or coupled with the carrier substrate to provide such properties alone or in combination with the carrier substrate. Optical properties can include uniformity, type and/or degree of reflectivity and/or refractivity or other optical properties of surfaces and/or interfaces and may include optical properties of the registration features.

In some embodiments, the carrier substrate can include and/or be coated with metallic or non-metallic materials, or one or more surfaces of the carrier substrate can be polished or otherwise treated to provide predetermined optical and/or electrical properties. For example, a layer of specular and/or diffuse reflective metal or other material can be laminated to or sprayed onto one or more sides of the carrier substrate. The metal layer can be coated with a layer of lacquer to provide an electrically insulating layer. Example metals include aluminum, silver and so forth. In some embodiments, such a layer can be contiguously or non-contiguously configured. A noncontiguous reflective layer, for example, can be formed by suitably configured ECEs or other components. Furthermore, the carrier substrate can include or be coated with one or more layers that provide one or more total internally reflective interfaces.

In some embodiments, the carrier substrate and/or other components of the lighting device can be configured to provide different thermal expansion coefficients (TECs) in different directions. For example, the carrier substrate can be provided with a TEC that better matches the TEC of the ECEs in a first planar direction than in a second planar direction. Accordingly, portions of ECEs in corresponding lighting devices can have a lower risk of de-bonding when longer portions of the ECEs are disposed substantially aligned along the directions of the better matched differential thermal expansion coefficient. Similar considerations may apply to differential TECs in directions perpendicular to the carrier device.

In some embodiments, a carrier substrate can be configured to enable and/or facilitate certain ways of fabrication of the lighting device, including formation of registration features that alone or in combination with the carrier substrate support or enable fluidic self-assembly (FSA) or other aspects, for example. Such a carrier substrate can have certain properties that hinder the operation of the lighting device to such a degree that the carrier substrate can be removed or replaced. In some embodiments, the carrier substrate provided initially during manufacture can be configured as a sacrificial component, also referred to as a sacrificial carrier substrate. A sacrificial carrier substrate can be configured to enable and/or facilitate certain aspects of the manufacture of a lighting device but can be removed at some point during fabrication and may not form part of the finished lighting device. In some embodiments, the sacrificial carrier substrate can be replaced with one or more cover layers, which may then again be referred to as a carrier substrate. Such a carrier substrate can be configured to provide refractive index matching, mechanical strength and/or protection, environmental protection or other aspects, for example. Such a carrier substrate can include one or more materials as noted herein.

In some embodiments, FSA can be performed without removal of the carrier substrate and/or the registration features. In such embodiments, the carrier substrate and/or the registration features can form part of the finished lighting device provided they do not interfere with the operation of the lighting device and/or provide functions required for the operation of the lighting device.

In some embodiments, the carrier substrate can include openings for escape of air, gas, light-transmissive substance (LTS) or other materials from the lighting device. Such openings may facilitate outgassing, escape of excess amounts of LTS or the relief of other materials during manufacture due to application of heat or pressure that can be applied to couple components of the lighting device. Suitably disposed and configured openings can aid in avoiding formation of unintended inclusions of air, gas, LTS or other materials within the lighting device in form of bubbles or otherwise, for example. According to some embodiments openings in the carrier substrate can be substantially sealed by LTS that escapes during manufacture of the lighting device.

In some embodiments, openings can be formed during manufacture and/or the carrier substrate can be provided with openings before commencing fabrication of the lighting device. Openings can be formed in a scribing or masking manner, by water jet, laser cutting, drilling, press method, etching or other method for forming openings. Openings can be disposed proximate and/or distal of registration features. Depending on the embodiment, openings can be formed in combination with registration features, ECEs and/or other components of the lighting device. Depending on the embodiment, openings in a multi-layer carrier substrate can be formed so that the operation of the function of the multiple layers is maintained.

In some embodiments, different openings can have different configurations, depending on the viscosity and the type of substance they are intended to relief. Openings can have rectangular, circular, trapezoidal or other cross sections and can be tapered towards or away from one or more opposing sides of the carrier substrate. Openings in the carrier substrate can range in size up to about the thickness of the carrier substrate or more.

### Electrically-Conductive Elements (ECEs)

Electrically-conductive elements (ECEs) may be configured in one or more formats. ECEs may include electrically conductive traces, wires, vias or other formats and can include metals, semimetals, semiconductors, electrically conductive oxides, reflowable solder material, non-metallic conductors or other electrically conductive materials. ECEs may be formed from conductive inks, pastes or other suitable fluids or solids. ECEs formed from fluids may be cured after deposition during manufacture of the lighting device.

Depending on the embodiment, ECEs may be disposed by employing processes comprising screen printing, laminating, ablating, chemical or physical vapor deposition; one or more forms of epitaxial deposition or other processes, for example. ECEs may be structured by masking, direct or indirect scribing including laser writing, screen printing or other processes. Structuring of ECEs can include deposition of one or more sacrificial and/or non-sacrificial masks including masking layers. Structuring can include one or more forms of etching, including, dry, wet, plasma, laser or otherwise light assisted etching during which at least portions of one or more materials may be removed.

Depending on the embodiment, ECEs may be operatively coupled with one or more sides of the carrier substrate. The operative coupling may be direct or indirect, for example, disposed on the carrier substrate, or disposed on one or more layers or other components of the lighting device that can be operatively coupled with the carrier substrate.

Depending on the embodiment, one or more ECEs can be configured to provide TECs that are close to TECs of components with which the ECEs can be coupled, including the carrier substrate; one or more cover layers or other components of the lighting device. Depending on the embodiment and in order to mitigate effects from large differential TECs, ECEs that are elongate and whose TEC better matches a first TEC of the carrier substrate in a first planar direction than a second TEC of the carrier substrate in a second planar direction, that ECE may be aligned with its elongate extension parallel to or including an small angle with the first direction. Similar considerations may apply to differential TECs of ECEs and other components in directions perpendicular to the carrier device.

According to some embodiments, one or more ECEs may be configured as reflectors, for example to provide a reflective layer for redirecting light emitted by the LEEs. Depending on the embodiment, the ECEs may be configured to cover predetermined areas of one or more sides of the carrier substrate separated by insulating/dielectric gaps that galvanically isolate the ECEs into a plurality of electrical paths required to provide electrical power to the LEEs. Optically reflective ECEs may be separated by gaps with a predetermined width to cover a predetermined portion of a side of the carrier substrate and reflect at least a predetermined portion of light provided by the LEEs. Gaps may be narrow to increase the portion of light that may be reflected. Depending on the embodiment, such optically reflective ECEs may be formed from metals or other materials including aluminum, silver, TiO₂-polycarbonate compound material with up to 20% or more weight percent TiO₂, for example. Such ECEs as well as other components comprising metals, for example, may further be configured to aid in heat dissipation and limitation of temperature-induced stress gradients within the lighting device. Furthermore, ECEs may be configured in combination with methods for controlling drive-current to provide a predetermined reactance, to limit undesired capacitive or inductive effects and/or electrostriction.

Depending on the embodiment, the ECEs may be embedded in one or more layers, separated from one another as well as other components by one or more suitably configured electrically insulating/dielectric material. Such material may be configured as a contiguous layer or a layer of non-contiguous material covering the ECEs.

Depending on the embodiment, ECEs may be configured to substantially extend into indentations, if so provided by the registration features, or in a nominally planar fashion without substantially extending into indentations. Accordingly, different processes and/or sequences of processes for operatively disposing ECEs may be employed as further discussed herein.

### Light-Transmissive Substance

The light-transmissive substance (LTS) may be used to aid in the operative disposition of the LEEs. LTS may be employed to mechanically or optically couple components of the lighting device. Depending on the embodiment, the LTS may be configured to provide an optical interface with a predetermined refractive index difference/match with the LEEs, provide a predetermined optical coupling between the LEEs and other components; to provide a mechanical bond between components, electrically insulate components, provide some degree of environmental insulation against entering of moisture or other agents, form one or more components of the lighting device, provide a light-exit surface from the lighting device to the ambient and/or provide other functions.

The LTS may be formed from or include one or more substances with suitable optical properties, viscosity, elasticity, flexibility adhesive, UV resistance, moisture diffusion resistance and/or other properties. The LTS may be disposed in a fluid form and then cured during manufacture of the lighting device. Curing may occur in effect of cooling, polymerization, reaction with physical and/or chemical agents including light or other electromagnetic radiation, heat treatment, oxygen or other agents. Depending on the embodiment, the LTS may include LCM (light-converting material). Example LTSs may include thermoplastics, elastomers derived from natural or synthetic rubber, silicone, and/or other materials. Depending on the embodiment, the LTS may be molded, casted, free formed or otherwise shaped, for example. Shaping can include the employ of components of the lighting device, tools or other aids.

Depending on the embodiment, LTS can be disposed to encapsulate LEEs. In embodiments in which there are openings in the cover layers associated with the LEEs, the LTS can be used to fill at least a portion of the openings, form a refractive interface with the ambient, and optionally optically couple the LEEs to the cover layers. Depending on the embodiment, the refractive interface may be free formed or molded to achieve a predetermined shape and function of the refractive interface.

### Light-Converting Material (LCM)

According to some embodiments, the lighting device includes light-converting material (LCM) to convert at least a portion of the light provided by the LEEs. For example, one or more of the LEEs may be configured to provide blue or ultraviolet light that is converted by the LCM to provide white light with a predetermined correlated color temperature or other light.

Depending on the embodiment, the LCM may be disposed as a separate component directly coupled onto the LEEs or distal from the LEEs and while optically coupled with the LEEs, mechanically coupled to components other than the LEEs. Furthermore, LCM may be included within the carrier substrate, the light-transmissive substance, one or more of the cover layers, or other components of the lighting device.

### Registration Features

Depending on the embodiment, the registration features may be configured to facilitate manufacture and/or provision of certain properties to the lighting device. For example, registration features may be configured to aid in the disposition and/or alignment of the LEEs, the formation of ECEs, the alignment of electrical interconnection between the LEEs and the ECEs within portions of a flexible light sheet that are exposed to low mechanical stress due to shearing and/or bending of the light sheet. Furthermore, registration features may be configured to limit exposure of the lighting device to mechanical stress in the vicinity of the registration features by mitigating effects due to differential TECs proximate the LEEs in planar and/or perpendicular sections of the lighting device, to reflect and/or refract light from the LEEs in a predetermined manner and/or to provide other functions. Depending on the embodiment, the registration features may be substantially larger than the LEEs or of comparable size.

FIG. 1G shows a sectional view of a flexible lighting device 100 with preferred bending locations 175. The preferred bending locations 175 can be defined, for example, by the structural configuration and/or material properties of the components of the lighting device (e.g., a light sheet). In some embodiments, indentations can be provided in the carrier substrate and/or a cover substrate to move the bending locations away from the indentations (e.g., to the weakest points of the lighting device), such that the preferred bending locations 175 can be placed, for example, between the indentations to minimize bending forces and/or shifting the stress-neutral plane within the indentations. Placing the preferred bending locations 175 of the lighting device away from the indentations, and thus, the electrical connections between the LEEs and ECEs, can reduce the mechanical stress on the electrical connections during bending and shearing of the lighting device. Reducing mechanical stress on the electrical connections may reduce the susceptibility of failure of the lighting device due to failure of the electrical connections.

Depending on the embodiment, registration features may be configured to aid in machine-assisted deposition or self-assembly of LEEs and/or other components of the lighting device. Machine-assisted deposition can include steps of computer vision, pattern matching, automated alignment and deposition of components via machines, for example. Corresponding registration features may be configured to be optically recognizable in visible and/or non-visible portions of the electromagnetic spectrum.

Registration features may be formed on one or more sides of the carrier substrate and/or configured to match in shape with the LEEs and/or to provide electrostatic, magnetic, hydrogen and/or other noncovalent bonds such as Van der Waals or other attractive and/or repelling forces to suitably compatibly configured LEEs that may be disposed from free-flowing or other fluid modification, also referred to as FSA (fluidic self-assembly). Such LEEs may be configured to match and/or not match in shape or other aspect with one or more portions of the registration features. Registration features may be formed directly in or on the carrier substrate, in or on one or more layers, or other components or layers associated with the carrier substrate. Depending on the embodiment, registration features can include indentations and/or elements formed from suitable materials.

In some embodiments, a lighting device can be fabricated by forming multiple registration features (e.g., indentations) in a surface of a carrier substrate, where a surface of the registration features has a predetermined shape. LEEs can be operatively coupled with the registration features, for example by using a fluidic self-assembly (FSA) process. The FSA process can be based on hydrophobic or hydrophilic properties of a surface of the LEEs, the surface of the registration feature with the predetermined shape, and the surface of the carrier substrate outside the registration features.

In some embodiments, the surface of the LEEs can substantially conform with the surface of the registration features. Electrical conductors can be operatively coupled with the surface of the carrier substrate, electrical interconnections can be formed between the LEEs and the electrical conductors, and one or more cover layer can be operatively coupled with the carrier substrate to encapsulate the LEEs inside the registration features.

In some embodiments, the surface of the LEE and the surface of the registration features can be hydrophilic, and the surface of the carrier substrate outside of the registration features can be hydrophobic. In some embodiments, the surface of the LEE and the surface of the registration features can be hydrophobic, and the surface of the carrier substrate outside of the registration features can be hydrophilic.

According to some embodiments, portions of the ECEs may be configured to provide at least some functionality of registration features. For example, the portions of the ECEs proximate to the electrical interconnections may be configured to provide attractive electromagnetic fields when suitably energized in combination with adequately configured LEEs in order to facilitate self-assembly of free-flowing LEEs, LEEs from a corresponding emulsion, or other configuration of LEEs with the registration features.

Depending on the embodiment, the registration features can include indentations that can be of comparable size to the LEEs and that have a shape that substantially matches at least a portion of the LEEs. For example, the LEEs and the indentations may have matching substantially rectangular, trapezoidal, truncated pyramid, L-shaped, triangular-shaped, or other cross sections and can be sized so that each indentation accepts one LEE. Depending on the embodiment, the LEEs may be configured as LED dies or the optically active portion thereof and may consequently be up to 1 to 10² micrometer or more thick and up to a fraction of a millimeter or more wide and long. Indentations may be of similar or larger size. Forms of registration features other than indentations may be smaller and/or larger than the LEEs. Indentations may be formed by microreplication, embossing, stamping, drawing ablating, thermoforming, or by other methods. Thermoforming may employ heating and evacuating the carrier substrate against a mask, stamp or other carrier providing suitably formed surface structures.

Depending on the embodiment, registration features may be configured to provide certain optical functions. For example, indentations may be formed to refract and/or reflect light from the LEEs in a predetermined fashion.

Depending on the embodiment, the registration features may be configured as sacrificial components. In such a case, the registration features can be used to facilitate part of the manufacturing but can be removed at some point and may not form part of the finished lighting device. Depending on the embodiment, sacrificial registration features can be configured to form part of a sacrificial carrier substrate.

### Cover Layer(s)

Depending on the embodiment, the lighting device can include one or more cover layers. Each cover layer may be formed from one or more elemental or compound materials. Different cover layers may have different properties and may be bonded to one another as described herein or otherwise. Depending on the embodiment, one or more cover layers may be coupled with the carrier substrate or used to replace a sacrificial carrier substrate. One or more cover layers that can be used to replace a sacrificial carrier substrate can be referred to as a carrier substrate.

Cover layers can include materials including organic, inorganic, metallic, non-metallic, oxides, ceramic, dielectric, adhesives or other materials. Cover layers may include polypropylene (PP), polyethylene terephthalate (PET), polycarbonate, polyvinylidene fluoride such as Kynar™, lacquer, acrylic, rubber, polyphenylene sulfide (PPS) such as Ryton™, polysulfone, polyphenylene oxide (PPO) such as Noryl™, aluminum, titanium oxides such as TiO₂, LCM (light-converting material) and/or other materials or compounds thereof, for example. Depending on the embodiment, cover layers may be attached to or coupled with the LEEs, the carrier substrate, the ECEs and/or other components to provide such properties alone or in combination therewith.

Cover layers may be configured to provide or be associated via interfaces with other components to provide predetermined optical properties in relation to the LEEs. Depending on the embodiment, cover layers may be light transmissive, reflective and/or refractive, for example. Light-transmissive cover layers may be optically transparent, or translucent, for example. A cover layer may reflect and/or absorb substantial portions of light. The degree to which light is transmitted or reflected by cover layers may depend on the configuration of the particular embodiment of the lighting device and in which direction(s) light from the LEEs is intended to propagate within and/or be emitted from the lighting device.

Depending on the embodiment, the cover layers can include and/or be coated with metallic or non-metallic materials. One or more surfaces of cover layers may be polished or otherwise treated to provide predetermined optical and/or electrical properties. For example, a cover layer can include specular and/or diffuse reflective metal or other material that may be laminated to or sprayed on another component. Metallic cover layers may be electrically separated with a layer of insulating material from other components. Example metals include aluminum, silver and so forth.

According to some embodiments, cover layers include openings associated with the LEEs for deposition and coupling of light-transmissive substance with the LEEs. The openings and/or the light-transmissive substance may be configured to facilitate escape of light from the LEEs via the light-transmissive substance into the ambient and/or optical coupling of the LEEs with the cover layers. Light from the LEEs may be dispersed via the light-transmissive substance and/or the cover layers to control apparent brightness variations when the lighting device is directly viewed during operation. Depending on the embodiment, sizes of such openings may be up or larger than the extension of the LEEs and/or the registration features.

Depending on the embodiment, cover layers can be provided with openings before they can be disposed to form part of the lighting device and/or openings may be formed after their deposition. Openings may be formed in a scribing or masking manner, by water jet, laser cutting, drilling, pressing, ablating, sublimating, evaporating, etching or other method for forming openings.

Depending on the embodiment, different openings can have different configurations, depending on the shape, size or other properties of the particular LEEs and/or registration features they are associated with. Openings may have rectangular, circular, trapezoidal or other cross sections. Depending on the embodiment, one or more cover layers may be formed from the light-transmissive substance. Depending on the embodiment, one or more cover layers may be configured to provide an environmental barrier against diffusion of moisture or other environmental agents, for example.

### Manufacturing—Further Details

According to embodiments of the present technology, a light sheet is manufactured in a number of steps including: providing a carrier substrate; forming a plurality of registration features on a first side of the carrier substrate; operatively coupling a plurality of electrically conductive elements (ECEs) with the first side; operatively coupling a plurality of light-emitting elements (LEEs) with the registration features; forming electrical interconnections between the LEEs and the ECEs; and operatively coupling one or more cover layers with the LEEs. Depending on the embodiment, the manufacture may optionally include steps including: disposing a light-transmissive substance to at least partially surround the LEEs and removing/replacing the carrier substrate, for example.

Depending on the embodiment, steps of the manufacture may be performed in different sequences. For example, registration features can be formed before or after disposition of the ECEs; ECEs can be disposed before or after the LEEs are disposed. Furthermore, cover layers may be disposed before and/or after removal of the carrier substrate; openings in the cover layers can be formed before or after the cover layers are operatively coupled with other components of the lighting device

As illustrated in FIGS. 1C to 1F for example, the thickness and composition of the layers may be arranged so that a notional stress-neutral plane defined by zero shear and/or bending stress within lateral and/or perpendicular directions within the lighting device passes through the LEEs, or the electrical interconnections between the LEEs and the ECEs, or other portion of the lighting device. As such the lighting device may be configured to minimize stress and strain on the LEEs and/or electrical connections between the LEEs and the ECEs. According to some embodiments, the lighting device can be configured so that the LEEs and/or the contacts between the LEEs and the ECEs can be disposed within portions of the lighting device that are exposed to mechanical stress below predetermined levels during bending and shearing of the lighting device. It is noted that contacts between an LEE and respective ECEs may be formed on one or more surfaces of such an LEE. For example, the LEEs may be configured as lateral or vertical LEEs.

Depending on the embodiment, manufacture may employ steps required to manipulate components provided in substantially endless or piece-by-piece, solid or fluid configuration. For example, carrier substrate, cover layers and/or other components may be provided in a web, sheet or string configuration from a roll, extrusion, stack, or other supply. Materials that can be initially provided in a liquid format to form components of the lighting device can be cured in a number of ways as described herein.

Depending on the embodiment, LEEs may be disposed in a number of ways including piece-by-piece disposition via automated mechanical manipulators, fluidic self-assembly or in other ways. LEEs that can be disposed via fluidic self-assembly can be provided in a suitable emulsion. Fluidic self-assembly can be assisted by application of ultrasonic or other sonic vibrations, application of electromagnetic fields, light or other forces. LEEs that are disposed via mechanical manipulators can be provided from one or more reels, in a loose format or otherwise provided.

Depending on the embodiment, electrical interconnections between the LEEs and the ECEs may be formed using wire bonds, tape-automated bonding, reflow or other solder, flip-chips with plated, deposited, screened or bonded interconnect pins, bumps, electrically isotropically or anisotropically conductive adhesives, conductive solder paste, solder vias to LEE bond pads, or other substances and/or corresponding processes. Wire bonds may be formed between electrical contacts of the LEEs and the ECEs. Electrically conductive adhesives include graphite, nickel, silver and/or other electrically conductive epoxies. ECEs may be disposed in the form of wirebonds and directly electrically connected to suitably configured LEEs. Wirebonds may be formed with a bonding machine. ECEs may be disposed from reflow solder or similar substances but not reflowed until after the LEEs have been disposed, thereby integrally forming electrical interconnections from the LEEs directly to the ECEs.

The technology will now be described with reference to specific examples. It will be understood that the examples are intended to describe aspects of some embodiments of the technology and are not intended to limit the technology in any way.

### EXAMPLES

### Example 1

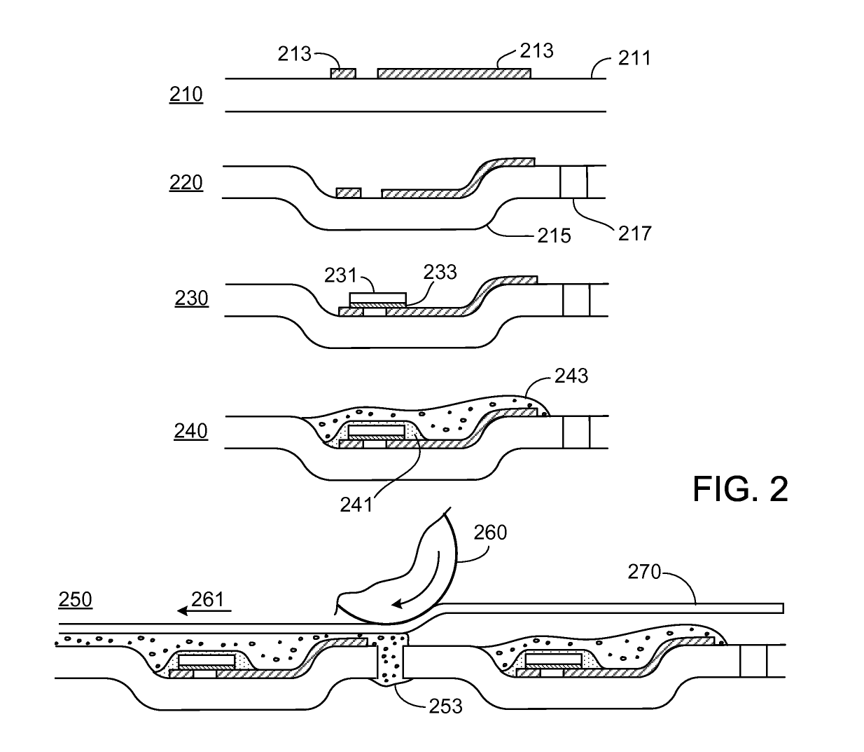

FIG. 2 illustrates a sequence of cross sections of portions of an example lighting device during select steps 210, 220, 230, 240 and 250 of an example manufacturing method according to some embodiments of the present technology. The example lighting device includes a carrier substrate 211, ECEs 213, LEEs 231, electrical interconnections 233, light-converting material 241, silicone (as an example of light-transmissive substance) 243 and a cover layer 270. The carrier substrate 211 is embossed during step 220 to form indentations 215. The openings 217 also referred to as escape channels may be formed via laser drilling or die cutting. The lighting device may be configured as a sheet or string, for example. FIG. 2 illustrates only portions of the lighting device with one or two LEEs. One LEE is shown in steps 210 to 240; two LEEs are shown in step 250.

One or more components of the example lighting device may be provided in an endless sheet, for example a web configuration (e.g., provided in a continuous process on a substrate that is unwound from a roll). The example lighting device may consequently be manufactured and provided in a corresponding format. As such the example lighting device may be cut into pieces after manufacture.

Initially (not illustrated), the carrier substrate 211 provided, cleaned and plasma etched. Cleaning, plasma etching and/or other forms of treatment are performed to facilitate adhesion of successively deposited components, to provide predetermined optical or other properties to one or more surfaces of the carrier substrate. The carrier substrate 211 includes multiple layers (not illustrated) that are configured to provide predetermined optical, electrical and/or other properties on at least a first side. For example, the carrier substrate 211 may include layers of PP, PET, Kynar™, reflective aluminum or TiO₂, polycarbonate and various adhesives.

ECEs 213 are subsequently deposited on the first side as indicated in step 210. The ECEs 213 are screen-printed from a suitable conductive paste. The assembly of the carrier substrate 211 and the ECEs 213 is subsequently embossed to form the indentations 215 and die cut or laser drilled to form the openings 217 in step 220. According to another example, the ECEs 213 are disposed after the carrier substrate 211 is embossed. The ECEs 213 are subsequently cured or reflowed and the LEEs 231 are attached with conductive epoxy to form the electrical interconnections 233 in step 230. According to another example, the LEEs 231 are disposed directly onto the uncured ECEs 213. The ECEs 213 are then cured to form electrical interconnections with the LEEs 231.

The LEEs 231 are configured and disposed to emit substantial amounts of light away from the carrier substrate 211. It is noted that LEEs of other lighting devices may be disposed and/or configured differently. Furthermore, different LEEs within a lighting device may be differently oriented, emit nominally different light or may differ in other aspects of their configuration.

The LEEs 231 are subsequently coated with LCM (light converting-material) in step 240. The LEEs 231 may be configured to emit blue or UV light, and are coated with light-converting material 241 to convert a portion of the blue light or substantially all UV light into substantially white light.

Predetermined amounts of silicone 243 are then disposed over the resulting assembly at least proximate the LEEs 231. The new assembly is then laminated with a cover layer 270 to sandwich the LEEs and the ECEs between the cover layer 270 and the carrier substrate 211. During lamination, the openings 217 allow escape of excess light-transmissive substance from within the lighting device. The amount of silicone 243 is sufficient to fill at least a portion of and seal the openings 217 in effect of the lamination.

The cover layer 270 is light-transmissive to allow light from the LEEs to escape into the ambient in a predetermined way. The cover layer 270 may be transparent, translucent or otherwise light-transmissive. The cover layer 270 is further configured to seal the lighting device from certain environmental agents to maintain predetermined operational conditions of the lighting device and its components in order to control penetration of moisture, UV light or other corrosive agents into the lighting device. The cover layer 270 can include multiple layers (not illustrated). Such layers may then be referred to as cover layers. For example, the cover layer 270 can include layers of PP and PET bonded to one another and/or other components of the lighting device via one or more adhesives.

The lamination process, schematically indicated in step 250, is performed using one or more rollers 260 (only one illustrated in FIG. 2) to provide predetermined pressure to form the example lighting device. One or more rollers may be kept at a predetermined temperature to facilitate the lamination process. Additional heat and/or temperature control of the lighting device during lamination may be provided via infrared or other forms of radiation, or by establishing contact with adequately heated/cooled manufacturing tools. Two fixed rollers may be used and configured to move the lighting device in a direction 261, or one roller may be used and rolled opposite direction 261, provided the lighting device is adequately supported on the side opposite the one roller. One or more of the rollers may be configured with a surface that adequately matches structure (elevations and so forth) of the outside surfaces of the lighting device.

Space underneath the LEEs between the ECEs may be configured to permit penetration of silicone or it may be filled with other substances before deposition of the LEEs, for example. Thermal coupling and heat transfer may be improved if such space is filled with adequate substances.

The example lighting device may be as thin as about 1 mm or thinner. Some example embodiments may be as little as about 20 micrometer to about 5 micrometer thick. The example lighting device may be configured to provide certain degrees of flexibility, for example to allow bending, rolling or other deformations within predetermined ranges.

### Example 2

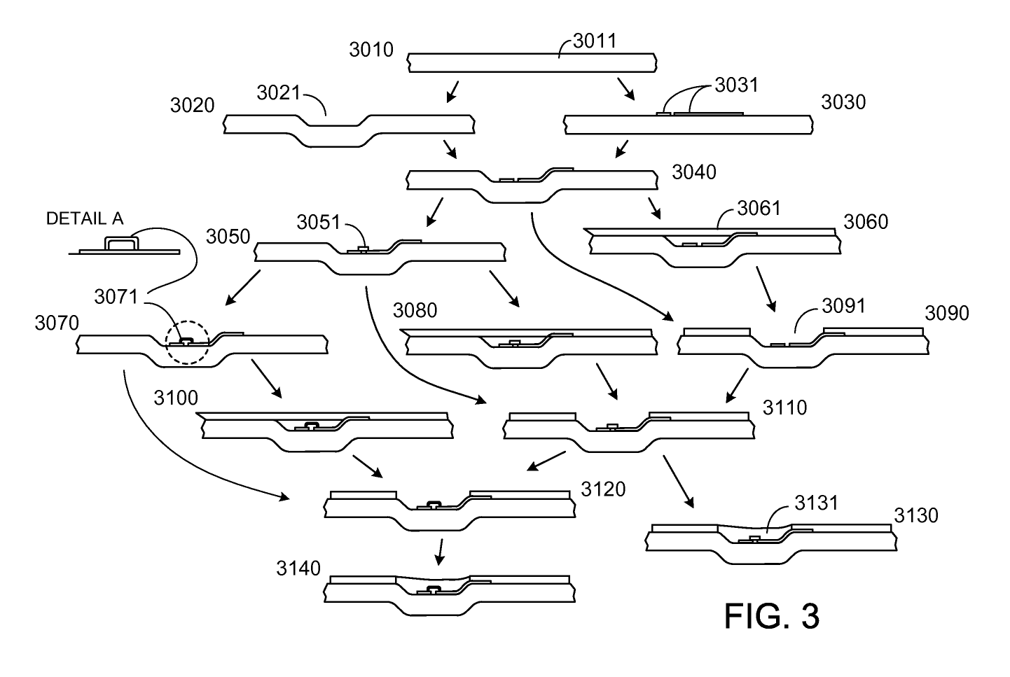

FIG. 3 illustrates sequences of cross sections of two example lighting devices during select steps 3010, 3020, 3030, 3040, 3050, 3060, 3070, 3080, 3090, 3100, 3110, 3120, 3130 and 3140 of an example manufacturing method according to some embodiments of the present technology. The example lighting devices include a carrier substrate 3011, ECEs 3031, LEEs 3051 with electrical interconnections (not illustrated) to the ECEs 3031, silicone (as an example of light-transmissive substance) 3131 and a cover layer 3061. One of the lighting devices produced by step 3140 also includes light-converting material 3071 as shown more clearly in Detail A in FIG. 3. The arrows indicate examples of how manufacturing steps may be performed in sequence. It is noted that not all sequence combinations are shown in FIG. 3. The lighting device may be configured as a sheet or string or predetermined length, area or other size, for example.

The carrier substrate 3011 is provided in step 3010. The carrier substrate 3011 can include one or more layers, it may be cleaned, treated or otherwise manipulated as described herein, for example. Step 3010 may be succeeded by step 3020 or step 3030, for example. The carrier substrate 3011 is embossed during step 3020 to form indentations 3021, and then operatively coupled with ECEs in step 3040. According to another example, ECEs 3031 are operatively coupled with the carrier substrate 3011 before the indentations are formed. It is noted that the ECEs may be formed from different source materials, or the steps may be performed in different manners, for example, depending on the sequence of steps in which the assembly (the portion of the lighting device) of step 3040 is formed.

Subsequently, LEEs 3051 may be operatively coupled with the ECEs in step 3050, a contiguous cover layer 3061 may be disposed in step 3060 and then openings 3091 may be formed therein as indicated in step 3090, or a cover layer already provided with openings 3091 may be disposed as indicated in step 3090.

The LEEs 3051 are configured and disposed to emit substantial amounts of light away from the carrier substrate 3011. It is noted that LEEs of other lighting devices may be disposed and/or configured differently. Furthermore, different LEEs within a lighting device may be differently oriented, emit nominally different light or may differ in other aspects of their configuration. The LEEs 3051 may be configured as a flip-chip top-emitting LED, for example.

The assembly of step 3050 (including the LEEs 3051) may be operatively coupled with a contiguous cover layer in step 3080 in which openings may then be formed therein as indicated by the assembly of step 3110. According to another example, the LEEs 3051 of the assembly of step 3050 may be coated with LCM 3071 and the resulting assembly operatively coupled with a cover layer as indicated by the assembly of step 3100. Openings may then be formed in the cover layer of the resulting assembly as indicated in step 3120.

According to an example, the LEEs of the assembly of step 3110 are coated with a LCM through the openings in the cover layer, and the openings are then substantially filled with silicone to seal the LEEs and the ECEs. According to another example, the openings in the assembly of step 3110 are directly sealed with silicone without formation of a coating of LCM on the LEEs. Depending on whether light from the LEEs needs to be converted, LCM may be absent from such a lighting device, or included in one or more other components, for example, in the silicone, the carrier substrate, the cover layer or other components.

Space between the LEEs, the ECEs and the carrier substrate may be filled with silicone or other electrically insulating substances, for example, before deposition of the LEEs or during deposition of the silicone. Thermal coupling and heat transfer may be improved if such space is filled with adequate substances.

The carrier substrate 3011 of the example lighting device may be made of Ryton™ with 30% (by weight or volume) glass fibers. The cover layer 3061 may be made of highly reflective TiO₂-including white polycarbonate. It is noted that other materials may be used for the carrier substrate and/or the cover layer.

### Example 3

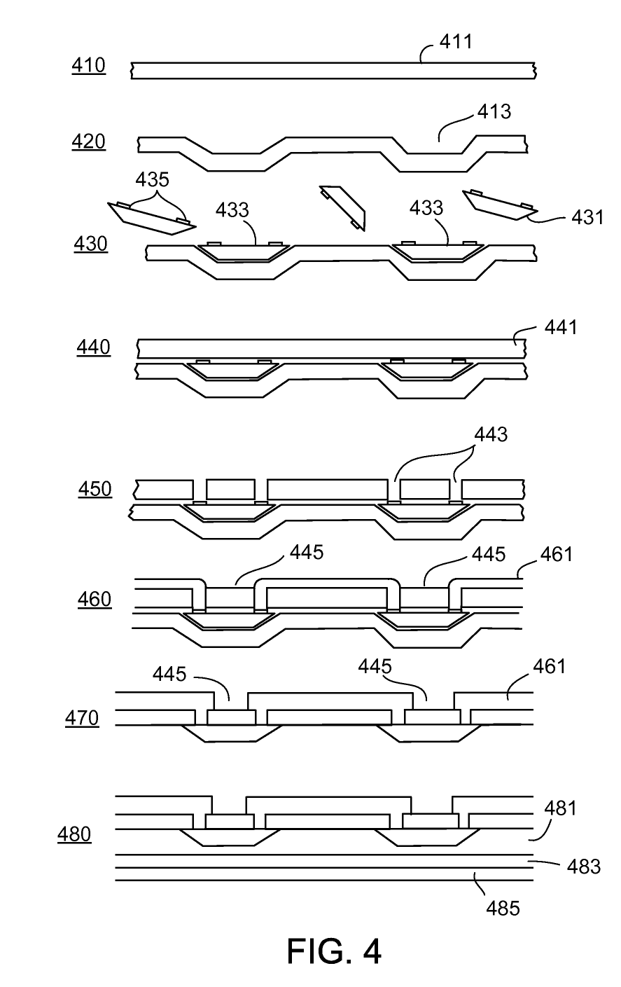

FIG. 4 illustrates a sequence of cross sections of portions of an example lighting device during select steps 410, 420, 430, 440, 450, 460, 470 and 480 of an example manufacturing method according to some embodiments of the present technology.

The example lighting device is formed from a subassembly comprising a sacrificial carrier substrate 411, LEEs 433 and ECEs 461. It is noted that other example lighting devices may be manufactured by utilizing sequences of one or more similar process steps without sacrificing the initial carrier substrate. The finished lighting device includes the subassembly without the sacrificial carrier substrate 411. The finished lighting device further includes cover layers 481, 483 and 485. In this example, the sacrificial carrier substrate provides properties required to enable fluidic self-assembly of the LEEs 433 from a fluid phase of LEEs 431, but does not provide optical and/or other properties required to enable operation of the example lighting device. It is noted that carrier substrates of other lighting devices may provide functions that enable fluidic self-assembly as well as optical and/or other properties required for the operation of the lighting device and hence may not need to be removed/replaced during manufacture.

The fluid phase of LEEs 431 can be an emulsion of suitably coated or otherwise treated LEEs 431 in a suitable liquid or other fluid medium, for example. Such an emulsion can include water, suitable surfactants and an environmental stabilizer to facilitate safe disposal. The LEEs 431, and/or the carrier substrate 411 may be electrically charged, magnetized, or coated with materials (not illustrated) to impart hydrophobic or hydrophilic properties, for example, or otherwise treated to maintain the LEEs 431 in a substantially free-flowing phase with or without material or immaterial agents. Immaterial agents may include electromagnetic, sonic or ultrasonic waves or other agents, for example.

The LEEs 431, 433 are configured as lateral LEEs with electrical contacts 435, which can include gold or other suitable materials to aid formation of electrical interconnections with predetermined properties. Such properties may include capabilities to form ohmic electrical interconnections, to provide a predetermined electromechanical bond with the ECEs 461, to provide predetermined heat transfer capability and suitable voltage drop via the ECEs 461 and/or other properties. The electrical contacts 435 may be disposed on one (as illustrated) or more (not illustrated) surfaces of the LEEs 431, 433. Depending on the embodiment, the LEEs 431, 435 may be about 0.1 mm thin or thinner, for example about 6 micrometer thin and from a few tens of micrometer up to several millimeter wide and/or deep.

The carrier substrate 411 is provided during step 410, registration features including indentations 413 are formed in step 420. The indentations may be formed by thermal microreplication. The indentations 413 are configured in form and size to substantially match the LEEs 431, 433 which themselves may be shaped for shape-specific assembly techniques. In step 430, LEEs 431 are provided in a fluidic-phase. Fluidic self-assembly of the LEEs 433 in step 430 may depend on the proper configuration of two or more of the registration features 413, the carrier substrate 411, the LEEs 431 and the fluidic self-assembly process invoked in step 430. Depending on the embodiment, fluidic self-assembly may be performed with or without (not illustrated) indentations. If indentations are used, they may be combined with other types of registration features. The LEEs 433 are configured and oriented to emit light substantially towards the carrier substrate 411, but may be aligned in a different direction in other examples. Furthermore, different LEEs may be oriented in different directions, depending on the embodiment.

In step 440, a layer of insulating material 441 is subsequently laminated onto the subassembly of step 430 to sandwich the LEEs 433 with the carrier substrate 411. The insulating material may include a polymer such as polyetherimide and/or other material operatively bonded with at least the LEEs 433 with a suitable adhesive (not illustrated). The layer of insulating material 441 and may be laminated with the subassembly, for example. Holes 443 are then formed in the insulating layer 441 to access the electrical contacts. Holes 443 may be formed via laser drilling or in other manners, for example with 366 nm laser light with which the drilling self arrests when the gold contacts of the LEEs 433 are reached. Positioning of the hole drilling may be assisted by machine vision, if the insulating material 441 is suitably light-transmissive, for example. Machine vision may be used to determine irregularities in the positioning, orientation, configuration or other aspects of the LEEs 433 and/or identify vacant indentations that may not include LEEs.

The surface may then be plasma cleaned or otherwise cleaned (not illustrated) before ECEs 461 are formed in step 460. The ECEs 460 may be formed by screen-printing a silver paste or other adequate conductive paste, for example. The silver paste or other conductive fluid may be cured immediately or after one or more of the following steps. Curing may be delayed until after certain steps of the manufacture if a better structural integrity of the cured conductive paste can be maintained thereafter. The ECEs 461 are configured to operatively interconnect the LEEs 433 in a predetermined manner, for example, in series, parallel or combination thereof. Gaps 445 within the ECEs are formed to operatively insulate the electrical contacts of the LEEs 433. If the manufacture is performed in an endless manner the gaps may be employed to form a continuous series connection of LEEs. In such a case, if the lighting device is more than one LEE deep, a continuous series connection of parallel-connected LEEs may be formed.

Depending on the embodiment, the sacrificial carrier substrate 411 is subsequently removed in step 470 from the subassembly of step 460. Depending on the embodiment, the sacrificial carrier substrate may be provided in a web, sheet or other format. According to an example, the carrier substrate is provided via the outer surface of an adequately sized roll or suitable belt. Depending on the configuration, the carrier substrate 470, may be peeled or rolled off, dissolved, etched away or otherwise removed, for example. The so exposed surfaces of the LEEs 433 may be coated, laminated or otherwise operatively coupled with one or more other components including one or more cover layers. Some components may be disposed substantially only onto exposed surfaces of the LEEs (not illustrated), others may be applied in form of a layer extending across the extension of the previously removed sacrificial carrier substrate. As such the sacrificial carrier substrate may be replaced with one or more other components. Such components may include LCM, for example. One or more cover layers may be configured as planarization layers.

Cover layer 481 is formed from a layer of adequate silicone that is subsequently cured. Cover layer 485 is formed of a sheet of PET. Cover layer 483 includes LCM. LCM may be also included in cover layer 481, or adhered to an outer layer of glass, such as a window pane, for example.

The lighting device may further include cover layers operatively coupled with the ECEs 461—not illustrated in FIG. 4. Such cover layers may be disposed before or after removal of the sacrificial carrier substrate.

It is noted that other example lighting devices may include vertical LEEs and as such may be configured in a different manner. Such lighting devices may be manufactured in ways that are similar or different from the example manufacturing method of FIG. 4.

While particular embodiments of the present technology have been shown and described, it will be obvious to those skilled in the art that changes and modifications may be made without departing from this technology in its broader aspects and, therefore, the appended claims are to encompass within their scope all changes and modifications that fall within the true spirit and scope of the technology.

1. A flexible lighting device, comprising:
a carrier substrate comprising a first surface, the first surface comprising a plurality of registration features;
a plurality of light emitting diode (LED) dies operatively coupled with the registration features;
a plurality of electrical conductors supported by the carrier substrate, wherein:
the electrical conductors are configured to electrically connect the LED dies to a source of power, and
each LED die of the plurality of LED dies has a plurality of surfaces and a plurality of contacts, the plurality of contacts being disposed on one or more surfaces of the plurality of surfaces and forming electrical interconnections with at least a portion of the electrical conductors; and
one or more cover layers operatively coupled with the carrier substrate to encapsulate the LED dies inside the registration features, wherein the electrical interconnections are disposed within portions of the lighting device that are less than a predetermined distance away from a stress-neutral plane of the lighting device.

2. The lighting device of claim 1, wherein the stress-neutral plane intersects one or more of the plurality of LED dies, wherein the stress-neutral plane intersects one or more of the electrical interconnections.

3. (canceled)

4. (canceled)

5. (canceled)

6. The lighting device of claim 1, further comprising a light transmissive substance disposed to at least partially surround the LED dies, wherein the light transmissive substance comprises silicone.

7. (canceled)

8. (canceled)

9. (canceled)

10. The lighting device of claim 1, wherein one or more of the cover layers comprise a plurality of openings that substantially correspond to locations of the LED dies, further comprising a light transmissive substance that at least partially fills at least some of the plurality of openings, wherein the light transmissive substance provides an optical coupling between the LED dies and the one or more of the cover layers.

11. (canceled)

12. (canceled)

13. The lighting device of claim 1, further comprising an optically reflective interface configured to reflect light emitted from the LED dies.

14-19. (canceled)

20. The lighting device of claim 1, wherein the registration features comprise a plurality of corresponding indentations in the carrier substrate, the indentations having one or more predetermined shapes.

21. The lighting device of claim 1, further comprising a light converting material operatively coupled with the LED dies, wherein (1) one or more of the LED dies are coated with the light-converting material, or (2) one of more of the cover layers comprise the light-converting material.

22. (canceled)

23. A method of manufacturing a flexible lighting device, the method comprising:
forming a plurality of registration features in a first surface of a carrier substrate;
operatively coupling a plurality of light emitting diode (LED) dies with corresponding registration features;
forming a plurality of electrical conductors supported by the carrier substrate, wherein:
the electrical conductors are configured to electrically connect the LED dies to a source of power, and
each LED die of the plurality of LED dies has a plurality of surfaces and a plurality of contacts, the plurality of contacts being disposed on one or more surfaces of the plurality of surfaces and forming electrical interconnections with at least a portion of the electrical conductors; and
operatively coupling one or more cover layers with the carrier substrate to encapsulate the LED dies inside the registration features, wherein the electrical interconnections are disposed within portions of the lighting device that are less than a predetermined distance away from a stress-neutral plane of the lighting device.

24. The method of claim 23, wherein the stress-neutral plane intersects (1) one or more of the plurality of LED dies, (2) one or more of the electrical interconnections, or (3) both.

25. The method of claim 23, wherein the LED dies are configured and disposed to emit light substantially away from the first surface.

26. (canceled)

27. The method of claim 23, further comprising:
disposing a light transmissive substance to at least partially surround the LED dies.

28. (canceled)

29. (canceled)

30. The method of claim 27, further comprising:
forming openings in the carrier substrate to dispose of excess light transmissive substance during operatively coupling the one or more cover layers.

31. (canceled)

32. The method of claim 31, further comprising:
disposing a light transmissive substance to at least partially fill at least some of the plurality of openings, wherein the light transmissive substance provides an optical coupling between the LED dies and the one or more of the cover layers.

33. (canceled)

34. The method of claim 23, further comprising:
operatively coupling an optically reflective interface to the flexible lighting device, wherein the optically reflective interface is configured to reflect light emitted from the LED dies.

35-38. (canceled)

39. The method of claim 23, further comprising:
operatively coupling an electrically insulating layer with the first surface; and
operatively coupling the electrical conductors to the electrically insulating layer.

40.-80. (canceled)
